(19) United States
(12) Patent Application Publication
(10) Pub. No.: US 2021/0311137 A1
(43) Pub. Date: Oct. 7, 2021

(54) METHOD AND DEVICE FOR DETECTING STATE OF FLEXIBLE SCREEN, ELECTRONIC DEVICE, AND STORAGE MEDIUM

(71) Applicant: BEIJING XIAOMI MOBILE SOFTWARE CO., LTD., Beijing (CN)

(72) Inventor: Chaoxi CHEN, Beijing (CN)

(73) Assignee: BEIJING XIAOMI MOBILE SOFTWARE CO., LTD., Beijing (CN)

(21) Appl. No.: 17/020,726

(22) Filed: Sep. 14, 2020

(30) Foreign Application Priority Data
Apr. 3, 2020 (CN) 202010257813.4

(51) Int. Cl. G01R 33/07; G01D 5/14; H04M 1/02

(52) U.S. Cl. CPC G01R 33/072; H04M 1/0268; G01D 5/145

(57) ABSTRACT

The present disclosure relates to a method and device for detecting a state of a flexible screen, an electronic device and a storage medium. The electronic device includes: a flexible screen; a rotating shaft, positioned on a back surface of the flexible screen and configured to change a state of the flexible screen through rotation of the rotating shaft; a magnet, at least partially fixed on the rotating shaft, a connecting direction of two magnetic poles of the magnet being vertical to an axial direction of the rotating shaft; and a magnetic field sensor, positioned on the back surface of the flexible screen and configured to detect a magnetic field formed by the magnet moving together with the rotating shaft and obtain a detection parameter, the detection parameter being at least configurable to determine the state of the flexible screen.

### CROSS-REFERENCE TO RELATED APPLICATION

This application is based upon and claims priority to Chinese Patent Application No. 202010257813.4, filed on Apr. 3, 2020, the entire content of which is incorporated herein by reference for all purposes.

### TECHNICAL FIELD

The present disclosure generally relates to the technical field of electronics, and more particularly, to a method and device for detecting a state of a flexible screen, an electronic device, and a storage medium.

### BACKGROUND

Flexible screen has become one of development trends of display screens of electronic devices. An electronic device with a flexible screen may be provided with a foldable part driving the flexible screen to be folded, thereby achieving various states for use. For example, the flexible screen may be unfolded to a state of a large display screen, the flexible screen is folded to reduce an area occupied by the electronic device and make it convenient to carry, or a secondary display screen may be arranged on an outer side of the electronic device in a folded state to display a simple picture such as time and the like; and therefore, the electronic device may be flexibly used in multiple manners.

However, under different states, different application interfaces in the use of the electronic device are required. Therefore, how to determine a state of a flexible screen of an electronic device becomes one of important technical problems in the technology.

### SUMMARY

According to a first aspect of the present disclosure, an electronic device with a flexible screen is provided, which may include: the flexible screen, a rotating shaft, a magnet, and a magnetic field sensor.

According to a second aspect of the present disclosure, a method for detecting a state of a flexible screen for an electronic device is provided, which may be applied to any abovementioned electronic device and include that: a magnetic field formed by a magnet moving together with a rotating shaft is detected, and at least one detection parameter is obtained; and a state of a flexible screen is determined according to the detection parameter.

According to a third aspect of the present disclosure, a device for detecting a state of a flexible screen is provided, which may at least include a processor and a memory configured to store executable instructions executable by the processor, the processor is configured to run the executable instructions to execute the steps in any method for detecting a state of a flexible screen.

According to a fourth aspect of the present disclosure, a non-transitory computer-readable storage medium is provided, in which computer-executable instructions may be stored, the computer-executable instructions being executed by a processor to implement the steps in any method for detecting a state of a flexible screen.

It is to be understood that the above general descriptions and detailed descriptions below are only exemplary and explanatory and not intended to limit the present disclosure.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a structure diagram of an electronic device, according to an exemplary embodiment.

FIG. 2 is a structure diagram of a cylindrical magnet, according to an exemplary embodiment.

FIG. 3 is a structure diagram of a U-shaped magnet, according to an exemplary embodiment.

FIG. 4 is a flow chart showing a method for detecting a state of a flexible screen, according to an exemplary embodiment.

FIG. 5 is a physical structure block diagram of an electronic device, according to an exemplary embodiment.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the present disclosure. Instead, they are merely examples of apparatuses and methods consistent with aspects related to the present disclosure as recited in the appended claims.

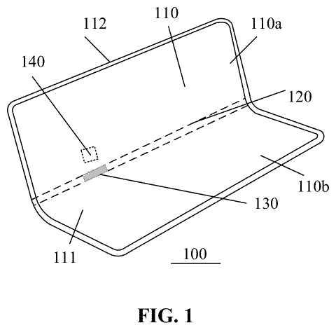

FIG. 1 is a structure diagram of an electronic device, according to an exemplary embodiment. As illustrated in FIG. 1, the electronic device 100 includes: a flexible screen 110, a rotating shaft 120, a magnet 130 and a magnetic field sensor 140. The flexible screen 110 may include a front surface 111 for displaying images and/or videos and a back surface 112 opposite to the front surface 111. The flexible screen 110 may include two sub-screens 110a and 110b configured to rotate about the rotating shaft 120.

The rotating shaft 120 is positioned on a back surface 112 of the flexible screen 110 and configured to change a state of the flexible screen 110 through rotation of the rotating shaft 120. The state of the flexible screen 110 may indicate the position, posture, or attitude of the flexible screen 110. For example, the state of the flexible screen 110 may include a folded state and an unfolded state, where the folded state may further include different states or positions with different folding angles between the two sub-screens 110a and 110b of the flexible screen 110.

The magnet 130 is at least partially fixed on the rotating shaft 120, and a connecting direction of two magnetic poles of the magnet 130 is vertical to an axial direction of the rotating shaft 120.

The magnetic field sensor 140 is positioned on the back surface of the flexible screen 110 and is configured to detect a magnetic field formed by the magnet 130 moving together with the rotating shaft 120 and obtain at least one detection parameter. The detection parameter is at least configurable to determine the state of the flexible screen 110.

In the embodiment of the present disclosure, the flexible screen covers a surface of the electronic device, and may be hidden in the electronic device, namely not exposed from an outer surface of the device, in a folded state. The flexible screen may display a picture as a full screen in an unfolded state. The rotating shaft is at a position where the flexible screen is folded on the back surface of the flexible screen, and rotates to drive the flexible screen to be folded, and then changes the state of the flexible screen.

The magnet is fixed at the rotating shaft and configured to generate the magnetic field. A direction of the magnetic field is vertical to the axial direction of the rotating shaft, such that the connecting line of the two magnetic poles, i.e., a pole N (north pole) and a pole S (south pole), of the magnet is vertical to the axial direction of the rotating shaft. The magnet may be a part of the rotating shaft. For example, a section of the rotating shaft is made from a magnetic material, thereby forming the magnet. The magnet may also be in the rotating shaft or enclose the rotating shaft. When rotating the rotating shaft, the magnet may simultaneously rotate along with the rotating shaft, thereby changing the connecting direction of the pole N and the pole S and rotating the direction of the magnetic field.

The magnetic field sensor is nearby the magnet and may sense the magnetic field generated by the magnet. The detection parameter may be a magnetic field intensity or the magnetic field direction. Therefore, when the magnet rotates along with the rotating shaft, the magnetic field sensor may detect a changed magnetic field intensity or direction. That is, the magnetic field sensor may detect a present magnetic field intensity or direction of the magnet, and thus a rotation angle of the rotating shaft may be determined according to the magnetic field direction to determine the state of the flexible screen.

It is to be noted that, no matter whether the magnet is in a rotating state or a stationary state, the magnetic field may be generated and the magnetic field sensor may detect the corresponding magnetic field. Therefore, in a rotating process of the rotating shaft, namely in a changing process of the state of the flexible screen of the electronic device, the magnetic field sensor may detect the changed magnetic field. When the flexible screen is fixed, namely the rotating shaft is stationary, the magnetic field sensor may detect the present magnetic field and further determine a present state of the flexible screen.

Through the abovementioned structure, the rotation angle of the rotating shaft may be determined accurately through the fixed magnet and the magnetic field sensor to determine the state of the flexible screen, such that another component or application of the electronic device may conveniently perform corresponding data processing and the like according to the state of the flexible screen.

In some embodiments, the magnetic field sensor includes: at least two sensing elements, configured to detect magnetic fields in different directions and obtain detection parameters.

In the embodiment of the present disclosure, the magnetic fields in different directions may be sensed through the at least two sensing elements respectively, and the rotation angle of the rotating shaft may be obtained through detection parameters such as magnetic field intensities in different directions and the like. For example, an x-axis direction of a rectangular coordinate system is parallel to a surface of the flexible screen of the electronic device and vertical to the axial direction of the rotating shaft. A y-axis direction is the axial direction of the rotating shaft, and a z-axis direction is a direction vertical to a plane where the x axis and the y axis are located. Herein, magnetic field intensities may be detected in the x-axis direction and z-axis direction of the rectangular coordinate system respectively, and a rotation angle of the magnetic field direction may be obtained according to an arc tangent value of a ratio of the magnetic field intensities in the two directions, thereby determining the rotation angle of the rotating shaft.

In some embodiments, the sensing element is a Hall element; extension directions of the at least two Hall elements are mutually vertical; and the detection parameter includes a Hall voltage sensed by the Hall element.

In the embodiment of the present disclosure, the magnetic field sensor may utilize a Hall principle and detect the magnetic field intensity through the principle that a Hall element generates a Hall voltage under the action of a magnetic field. The mutually vertical Hall voltages are generated in the magnetic field through the at least two mutually vertical Hall elements, and then the rotation angle of the magnetic field may be determined according to an arc tangent value of a ratio of every two Hall elements, so as to determine the rotation angle of the rotating shaft.

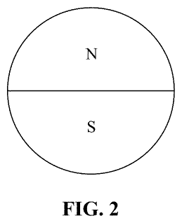

In some embodiments, as illustrated in FIG. 2, the magnet includes a cylindrical permanent magnet 200, the cylindrical permanent magnet includes a solid cylindrical permanent magnet or a hollow cylindrical permanent magnet, and an interface of two magnetic poles (N/S) of the cylindrical permanent magnet overlaps a tangent plane along any diameter of the cylindrical permanent magnet.

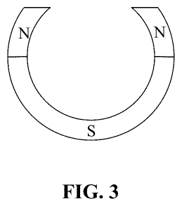

Or, as illustrated in FIG. 3, the magnet includes a U-shaped permanent magnet, and an interface of two magnetic poles (N/S) of the U-shaped permanent magnet is a plane where a centerline of the U-shaped permanent magnet is located.

When a shape of the magnet is a cylinder, a uniform magnetic field may be generated in a rotation direction of the rotating shaft, and the angle may be conveniently calculated. The U-shaped magnet is convenient to manufacture and generates a magnetic field similar to that generated by the cylindrical permanent magnet. Regardless of the shape of the magnet, the interface of the two magnetic poles is parallel to the axial direction of the rotating shaft. In this way, during the rotating process of the rotating shaft, the magnetic field generated by the magnet may change along with changing of the rotation angle, thereby bringing convenience to detection of the magnetic field sensor.

In some embodiments, when the flexible screen is in an unfolded state, an interface of the two magnetic poles of the magnet is parallel to the flexible screen.

When the interface of the two magnetic poles of the magnet is parallel to the flexible screen when the flexible screen is in the unfolded state, the rotation angle is 0 degree. Then, when the flexible screen is folded to a certain included angle along with rotation of the rotating shaft, the interface of the two magnetic poles of the rotating shaft is also correspondingly rotated by a certain angle. Therefore, the rotation direction is set in such a manner to bring convenience to data processing.

In some embodiments, a length of the magnet along the axial direction of the rotating shaft is greater than a length of the magnetic field sensor.

Since the intensity of the magnetic field generated by the magnet is directly proportional to a size of the magnet, for causing the magnetic field sensor to sense a sufficient magnetic field, the magnet requires a relatively large size. Herein, a relatively long magnet longer than the magnetic field sensor may be arranged in the axial direction, thereby causing the magnetic field sensor to sense the magnetic field generated by the magnet.

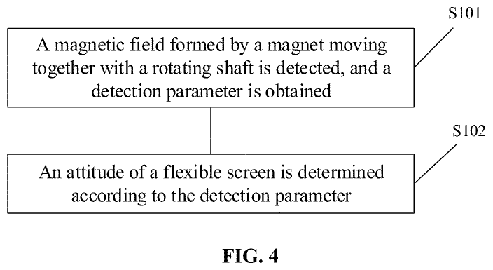

The embodiments of the present disclosure also provide a method for detecting a state of a flexible screen for an electronic device, which is applied to any abovementioned electronic device. As illustrated in FIG. 4, the method includes operations as follows.

At S101, a magnetic field formed by a magnet moving together with a rotating shaft is detected, and at least one detection parameter is obtained.

At S102, a state of a flexible screen is determined according to the detection parameter.

Herein, the magnetic field generated by the magnet may be detected by use of a magnetic field sensor to obtain the detection parameter. The detection parameter may be detection parameters corresponding to magnetic field components in at least two directions. When rotating the rotating shaft and driving the flexible screen to be folded to form different included angles, magnitudes of the magnetic field components detected by the magnetic field sensor in different directions are different, such that a rotation angle of the rotating shaft may be determined so as to determine the state of the flexible screen.

In some embodiments, the operation that the magnetic field formed by the magnet moving together with the rotating shaft is detected and the detection parameter is obtained includes that: magnetic fields in at least two different directions are detected, and induced voltages in the at least two different directions are obtained. The induced voltages are detection parameters, and the at least two different directions are mutually vertical.

Herein, a Hall effect detection principle is adopted for magnetic field detection. In a magnetic field environment, a semiconductor material (a Hall element) that a current is applied to may generate an electric potential difference, i.e., a Hall voltage, vertical to a direction of the current under the action of the magnetic field. Moreover, a magnitude of the Hall voltage is directly proportional to a magnetic field intensity. The abovementioned induced voltage is the Hall voltage generated by the Hall element under the action of the magnetic field.

Therefore, a component of the magnetic field intensity of the magnetic field in a direction may be determined by use of the magnitude of the detected induced voltage. Components of the magnetic field intensity in different directions may be detected by use of Hall elements in at least two different directions. Furthermore, an angle change of the magnetic field is further determined.

In some embodiments, the operation that the state of the flexible screen is determined according to the detection parameter includes that: a rotation angle of the magnet is determined based on a mapping relationship between an arc tangent value of a ratio of the induced voltages in the at least two directions and the rotation angle of the magnet; and the state of the flexible screen is determined according to the rotation angle.

Directions of magnetic fields generated by the magnet under different rotation angles are also different, and correspondingly, detected induced voltages in the at least two directions are also different. Therefore, the rotation angle of the magnet may be determined according to the mapping relationship between the arc tangent value of the ratio of the induced voltages detected in the at least two directions in the abovementioned embodiment and the rotation angle so as to determine the state of the flexible screen. For example, when the rotation angle is 180 degrees, the flexible screen is in an unfolded state, and when the rotation angle is 0 degree, the flexible screen is in a folded state; or, when the rotation angle is 180 degrees, the flexible screen is in the folded state, and when the rotation angle is 0 degree, the flexible screen is in the unfolded state.

In some embodiments, the electronic device includes at least two magnets, and each magnet corresponds to at least one magnetic field sensor; the operation that the state of the flexible screen is determined according to the rotation angle includes that: an average rotation angle is determined according to rotation angles detected by each magnetic field sensor, and the state of the flexible screen is determined according to the average rotation angle.

In the embodiment of the present disclosure, the magnet and the magnetic field sensor correspondingly form a group of detection components. For improving the detection accuracy, multiple groups of detection components may be arranged in the electronic device, namely at least two magnets and corresponding magnetic field sensors are arranged. For example, two magnets are arranged at different positions, and each magnet corresponds to two magnetic field sensors. Of course, only one magnet may be arranged, and a magnetic field sensor is correspondingly arranged on each of two sides of the rotating shaft of the electronic device.

In such a manner, rotation angles of the rotating shaft are determined through detection data obtained by multiple magnetic field sensors, and may be averaged to obtain the average angle, such that data errors caused by arrangement of only one group of detection components are reduced, and the detection accuracy is improved.

The embodiments of the present disclosure also provide the following example.

An electronic device with a foldable flexible screen includes a rotating shaft configured to drive the flexible screen to be folded. By rotating the rotating shaft by a certain angle to fold the flexible screen, a certain included angle is formed by two surfaces. For detecting a folded state of the flexible screen, i.e., the state of the flexible screen, in the embodiment of the present disclosure, a groove may be formed in the rotating shaft and a magnet may be placed in the groove. An interface of north and south poles of the magnet is parallel to an axial direction of the rotating shaft. In this way, when the magnetic rotates along with the rotating shaft, a connecting direction of the north and south poles may also rotate along with the rotating shaft of the magnet, thereby bringing convenience to detection. In addition, the magnet and the magnetic field sensor may also be arranged on two sides of the rotating shaft respectively to implement state detection.

In the embodiment of the present disclosure, a magnetic field is detected by use of a digital Hall sensor which may be arranged on any side in the two sides of the rotating shaft. When rotating the rotating shaft and driving the flexible screen to be folded, voltage changes shaped like sinusoidal waves may be detected in three mutually vertical detection directions of the Hall sensor. An arc tangent value of a ratio of voltage signals detected in any two detection directions forms a fixed corresponding relationship with the rotation angle. Before the electronic device is delivered, the corresponding relationship is determined by experiments. In a practical using process of the electronic device, the corresponding rotation angle may directly be determined according to detected data, thereby determining the state of the flexible screen.

The rotating shaft may also be hollow, and the magnet is arranged in the rotating shaft. A shape of the magnet may be U and may also be a cylinder. A circle center of the cylinder overlaps a circle center of the rotating shaft, and a tangent plane where any diameter, passing through the circle center, of the magnet is located in the axial direction is the interface of the north and south poles of the magnet. When the flexible screen is in the unfolded state, an interface of north and south poles of the cylindrical magnet may be parallel to a plane where the flexible screen is located, and in such case, it may be determined that the angle is 0 degree.

Magnetic field intensities in at least two directions, for example, an x-axis direction and a z-axis direction, are detected, a tangent value of a ratio of the two or another function relationship is calculated, and multiple groups of data may be detected by rotation to obtain a function relationship between the detected magnetic field intensities and rotation angles, thereby obtaining function relationships between magnetic field components of the magnetic field in different directions and states of the flexible screen for convenient use.

The magnetic field sensor may be connected with a processing chip through an inter-integrated circuit (I2C) or another communication circuit. The magnetic field sensor may be arranged at a main board of the electronic device or a small power interface board. However, it is to be noted that circuit lines around a position where the magnetic field sensor is arranged are required to be as few as possible, and meanwhile, a material for a component around it is also required to adopt a material that is relatively low in magnetic conductivity and unlikely to magnetize. Therefore, the magnetic field sensor and the magnet are unlikely to interfere with another component in the electronic device, and the condition of inaccurate detection caused by interference of the other component and circuit is also unlikely to occur.

In addition, for causing the magnetic field sensor to detect clear data, the intensity of the magnetic field may not be too low. Therefore, a size of the magnet is required to be large enough, including a relatively great radius and a relatively great length. For example, the length of the magnet may be greater than a length of the magnetic field sensor. In addition, for improving the detection accuracy, two magnetic field sensors may be arranged on two sides of one magnet, or multiple magnetic field sensors may be arranged on two sides of multiple magnets, and detection data is processed in an averaging manner, such that the detection accuracy is improved. Moreover, when one magnet or magnetic field sensor is damaged and disabled, standby magnets and magnetic field sensors are provided.

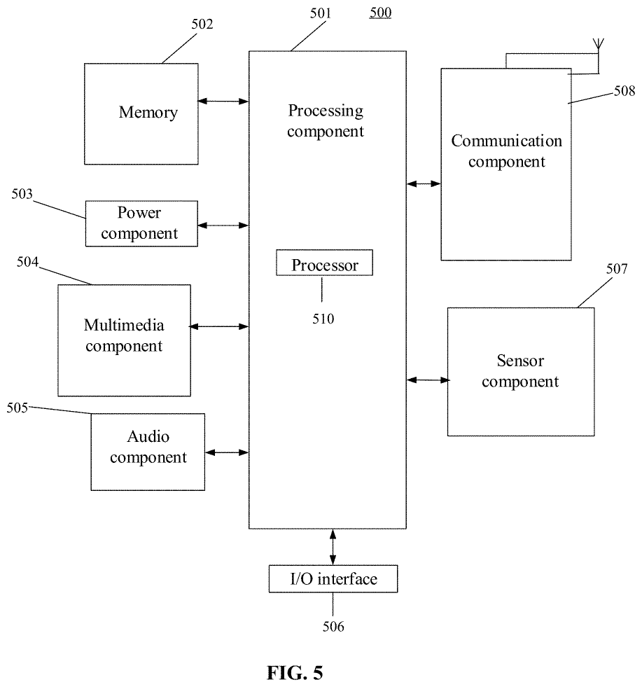

FIG. 5 is a physical structure block diagram of an electronic device 500, according to an exemplary embodiment. For example, the electronic device 500 may be a mobile phone, a computer, a digital broadcast terminal, a messaging device, a gaming console, a tablet, a medical device, exercise equipment, a personal digital assistant, and the like.

Referring to FIG. 5, the electronic device 500 may include one or more of the following components: a processing component 501, a memory 502, a power component 503, a multimedia component 504, an audio component 505, an input/output (I/O) interface 506, a sensor component 507, and a communication component 508.

The processing component 501 typically controls overall operations of the electronic device 500, such as the operations associated with display, telephone calls, data communications, camera operations, and recording operations. The processing component 501 may include one or more processors 510 to execute instructions to perform all or part of the steps in the abovementioned method. Moreover, the processing component 501 may further include one or more modules which facilitate interaction between the processing component 501 and other components. For instance, the processing component 501 may include a multimedia module to facilitate interaction between the multimedia component 504 and the processing component 501.

The memory 502 is configured to store various types of data to support the operation of the electronic device 500. Examples of such data include instructions for any applications or methods operated on the electronic device 500, contact data, phonebook data, messages, pictures, video, etc. The memory 502 may be implemented by any type of volatile or non-volatile memory devices, or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, and a magnetic or optical disk.

The power component 503 provides power for various components of the electronic device 500. The power component 503 may include a power management system, one or more power supplies, and other components associated with generation, management and distribution of power for the electronic device 500.

The multimedia component 504 includes a screen providing an output interface between the electronic device 500 and a user. In some embodiments, the screen may include a liquid crystal display (LCD) and a touch panel (TP). If the screen includes the TP, the screen may be implemented as a touch screen to receive an input signal from the user. The TP includes one or more touch sensors to sense touches, swipes and gestures on the TP. The touch sensors may not only sense a boundary of a touch or swipe action, but also detect a period of time and a pressure associated with the touch or swipe action. In some embodiments, the multimedia component 504 includes a front camera and/or a rear camera. The front camera and/or the rear camera may receive external multimedia data when the electronic device 500 is in an operation mode, such as a photographing mode or a video mode. Each of the front camera and/or the rear camera may be a fixed optical lens system or have focusing and optical zooming capabilities.

The audio component 505 is configured to output and/or input an audio signal. For example, the audio component 505 includes a microphone (MIC), and the MIC is configured to receive an external audio signal when the electronic device 500 is in an operation mode, such as a call mode, a recording mode and a voice recognition mode. The received audio signal may further be stored in the memory 502 or sent through the communication component 508. In some embodiments, the audio component 505 further includes a speaker configured to output the audio signal.

The I/O interface 506 provides an interface between the processing component 501 and peripheral interface modules, such as a keyboard, a click wheel, buttons and the like. The buttons may include, but are not limited to: a home button, a volume button, a starting button and a locking button.

The sensor component 507 includes one or more sensors configured to provide status assessments in various aspects for the electronic device 500. For instance, the sensor component 507 may detect an on/off status of the electronic device 500 and relative positioning of components, such as a display and small keyboard of the electronic device 500, and the sensor component 507 may further detect a change in a position of the electronic device 500 or a component of the electronic device 500, presence or absence of contact between the user and the electronic device 500, orientation or acceleration/deceleration of the electronic device 500 and a change in temperature of the electronic device 500. The sensor component 507 may include a proximity sensor configured to detect presence of an object nearby without any physical contact. The sensor component 507 may also include a light sensor, such as a complementary metal oxide semiconductor (CMOS) or charge coupled device (CCD) image sensor, configured for use in an imaging application. In some embodiments, the sensor component 507 may also include an acceleration sensor, a gyroscope sensor, a magnetic sensor, a pressure sensor or a temperature sensor.

The communication component 508 is configured to facilitate wired or wireless communication between the electronic device 500 and other devices. The electronic device 500 may access a communication-standard-based wireless network, such as a wireless fidelity (WiFi) network, a 2nd-generation (2G) or 3rd-generation (3G) network or a combination thereof. In an exemplary embodiment, the communication component 508 receives a broadcast signal or broadcast associated information from an external broadcast management system through a broadcast channel. In an exemplary embodiment, the communication component 508 further includes a near field communication (NFC) module to facilitate short-range communications. For example, the NFC module may be implemented based on a radio frequency identification (RFID) technology, an infrared data association (IrDA) technology, an ultra-wide band (UWB) technology, a Bluetooth (BT) technology, and other technologies.

In an exemplary embodiment, the electronic device 500 may be implemented by one or more application specific integrated circuits (ASICs), digital signal processors (DSPs), digital signal processing devices (DSPDs), programmable logic devices (PLDs), field programmable gate arrays (FPGAs), controllers, micro-controllers, microprocessors or other electronic components, and is configured to execute the abovementioned method.

In an exemplary embodiment, there is also provided a non-transitory computer-readable storage medium including instructions, such as included in the memory 502, executable by the processor 510 of the electronic device 500 for performing the abovementioned methods. For example, the non-transitory computer-readable storage medium may be a ROM, a random access memory (RAM), a compact disc read-only memory (CD-ROM), a magnetic tape, a floppy disc, an optical data storage device, and the like.

According to a non-transitory computer-readable storage medium, instructions in the storage medium are executed by a processor of a mobile terminal to cause the mobile terminal to execute any method in the abovementioned embodiment.

Other implementation solutions of the present disclosure will be apparent to those skilled in the art from consideration of the specification and practice of the present disclosure. This application is intended to cover any variations, uses, or adaptations of the present disclosure following the general principles thereof and including such departures from the present disclosure as come within known or customary practice in the art. It is intended that the specification and examples be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes may be made without departing from the scope thereof. It is intended that the scope of the present disclosure only be limited by the appended claims.

What is claimed is:

1. An electronic device, comprising:
a flexible screen;
a rotating shaft, positioned on a back surface of the flexible screen and configured to change a state of the flexible screen through rotation of the rotating shaft;
a magnet, at least partially fixed on the rotating shaft, a connecting direction of two magnetic poles of the magnet being vertical to an axial direction of the rotating shaft; and
a magnetic field sensor, positioned on the back surface of the flexible screen and configured to detect a magnetic field formed by the magnet moving together with the rotating shaft and obtain at least one detection parameter, the at least one detection parameter indicating the state of the flexible screen.

2. The electronic device of claim 1, wherein the magnetic field sensor comprises:
at least two sensing elements, configured to detect magnetic fields in different directions and obtain detection parameters.

3. The electronic device of claim 2, wherein the sensing element is a Hall element; extension directions of the at least two Hall elements are mutually vertical; and the at least one detection parameter comprises a Hall voltage sensed by the Hall element.

4. The electronic device of claim 1, wherein the magnet comprises a cylindrical permanent magnet, the cylindrical permanent magnet comprises a solid cylindrical permanent magnet or a hollow cylindrical permanent magnet, and an interface of two magnetic poles of the cylindrical permanent magnet overlaps a tangent plane along any diameter of the cylindrical permanent magnet.

5. The electronic device of claim 1, wherein the magnet comprises a U-shaped permanent magnet, and an interface of two magnetic poles of the U-shaped permanent magnet is a plane where a centerline of the U-shaped permanent magnet is located.

6. The electronic device of claim 3, wherein, in response to the flexible screen in an unfolded state, an interface of the two magnetic poles of the magnet is parallel to the flexible screen.

7. The electronic device of claim 1, wherein a length of the magnet along the axial direction of the rotating shaft is greater than a length of the magnetic field sensor.

8. A method for detecting a state of a flexible screen, applied to an electronic device, wherein the electronic device comprises a flexible screen, a rotating shaft, a magnet and a magnetic field sensor; the method comprising:
detecting a magnetic field formed by the magnet moving together with the rotating shaft, and obtaining at least one detection parameter; and
determining a state of the flexible screen according to the at least one detection parameter.

9. The method of claim 8, wherein detecting the magnetic field formed by the magnet moving together with the rotating shaft and obtaining the detection parameter comprises:
detecting magnetic fields in at least two different directions and obtaining induced voltages in the at least two different directions, wherein the induced voltages are detection parameters and the at least two different directions are mutually vertical.

10. The method of claim 9, wherein determining the state of the flexible screen according to the detection parameter comprises:
determining a rotation angle of the magnet based on a mapping relationship between an arc tangent value of a ratio of the induced voltages in the at least two directions and the rotation angle of the magnet; and
determining the state of the flexible screen according to the rotation angle.

11. The detection method of claim 10, wherein the electronic device comprises at least two magnets, and each magnet corresponds to at least one magnetic field sensor;
wherein determining the state of the flexible screen according to the rotation angle comprises:
determining an average rotation angle according to rotation angles detected by each magnetic field sensor, and
determining the state of the flexible screen according to the average rotation angle.

12. A non-transitory computer-readable storage medium, in which computer-executable instructions are stored, the computer-executable instructions being executed by a processor to implement a method for detecting a state of a flexible screen applied to an electronic device, wherein the electronic device comprises a flexible screen, a rotating shaft, a magnet and a magnetic field sensor; the method comprising:
detecting a magnetic field formed by the magnet moving together with the rotating shaft, and obtaining at least one detection parameter; and
determining a state of the flexible screen according to the at least one detection parameter.

13. The non-transitory computer-readable storage medium of claim 12, wherein detecting the magnetic field formed by the magnet moving together with the rotating shaft and obtaining the at least one detection parameter comprises:
detecting magnetic fields in at least two different directions and obtaining induced voltages in the at least two different directions, wherein the induced voltages are detection parameters and the at least two different directions are mutually vertical.

14. The non-transitory computer-readable storage medium of claim 13, wherein determining the state of the flexible screen according to the at least one detection parameter comprises:
determining a rotation angle of the magnet based on a mapping relationship between an arc tangent value of a ratio of the induced voltages in the at least two directions and the rotation angle of the magnet; and
determining the state of the flexible screen according to the rotation angle.

15. The non-transitory computer-readable storage medium of claim 14, wherein the electronic device comprises at least two magnets, and each magnet corresponds to at least one magnetic field sensor;
wherein determining the state of the flexible screen according to the rotation angle comprises:
determining an average rotation angle according to rotation angles detected by each magnetic field sensor, and
determining the state of the flexible screen according to the average rotation angle.
